(19) United States
(12) Patent Application Publication
(10) Pub. No.: US 2011/0165461 A1
(43) Pub. Date: Jul. 7, 2011

(54) ELECTRODE INCLUDING NANOCOMPOSITE ACTIVE MATERIAL, METHOD OF PREPARING THE SAME, AND ELECTROCHEMICAL DEVICE INCLUDING THE SAME

(75) Inventors: Kyung Soo PARK, Seoul (KR); Young Jin CHOI, Seoul (KR); Jin Gu KANG, Seoul (KR); Dae Hyun KIM, Seoul (KR); Dong Wan KIM, Seoul (KR); Jae Gwan PARK, Seoul (KR)

(73) Assignee: KOREA INSTITUTE OF SCIENCE AND TECHNOLOGY, Seoul (KR)

(21) Appl. No.: 12/976,812

(22) Filed: Dec. 22, 2010

(30) Foreign Application Priority Data
Jan. 5, 2010 (KR) 10-2010-0000290

(51) Int. Cl. H01M 4/48; H01M 4/52; H01M 4/54; H01M 4/50; B05D 5/12; C23C 14/34; H01G 9/155; B82Y 30/00

(52) U.S. Cl. 429/219; 429/218.1; 429/220; 429/231.5; 429/223; 429/231; 429/221; 429/224; 429/229; 427/77; 204/192.1; 361/502; 977/773; 977/762

(57) ABSTRACT

The present invention provides an electrode and a method of preparing the same. The electrode of the present invention is prepared by forming a nanostructured conductor comprising a metal or metal oxide on a substrate and forming an active material comprising metal oxide nanoparticles on the surface of the nanostructured conductor. The electrode of the present invention can be used in various electrochemical devices such as energy storage devices including secondary batteries, supercapacitors, etc., photocatalyst elements, thermoelectric elements, or composite elements thereof. Moreover, the electrode of the present invention can be applied to a lithium secondary battery, in which intercalation/deintercalation of lithium ions is performed, and especially applied to a negative electrode of the lithium secondary battery.

The electrode of the present invention includes a substrate and an active material layer formed on the substrate, the active material layer including a nanostructured conductor formed on the substrate and comprising a metal or metal oxide and an active material formed on the surface of the nanostructured conductor and comprising metal oxide nanoparticles.

### CROSS-REFERENCE TO RELATED APPLICATION

This application claims under 35 U.S.C. §119(a) the benefit of Korean Patent Application No. 10-2010-0000290 filed on Jan. 5, 2010, the entire contents of which are incorporated herein by reference.

### BACKGROUND

(a) Technical Field

The present invention relates to an electrode and a method of preparing the same and, more particularly, to an electrode used in an electrochemical device, such as a lithium secondary battery, etc., and a method of preparing the same.

(b) Background Art

Recently, with the rapid development of various information technologies in the electronic and mobile communication industries, portable electronic devices such as cellular phones, notebooks, PDAs, digital cameras, camcorders, etc., have come into wide use to meet the demands of electronic devices which are light in weight and small in size and thickness. Therefore, the development of batteries as drive sources for these devices has been drawing much attention.

Especially, with the development of electric vehicles such as pure electric vehicle, hybrid vehicle, etc., the use of batteries having high capacity, high density, high power, and high stability has been highlighted. Moreover, the development of batteries having a high charge/discharge rate has been an important issue.

The batteries which convert chemical energy into electrical energy are divided into primary batteries, secondary batteries, solar batteries, etc., according to the types and characteristics of basic materials.

Primary batteries, such as manganese batteries, alkaline batteries, mercury batteries, etc., generate energy through an irreversible reaction, and thus their capacity is large. However, they cannot be recycled and have various problems such as energy inefficiency, environmental pollution, etc.

Secondary batteries, such as lead batteries, nickel-metal hydride batteries, nickel-cadmium batteries, lithium ion batteries, lithium polymer batteries, lithium metal batteries, etc., generate energy through an reversible reaction, and thus they can be recycled and are environmental-friendly.

Meanwhile, the lithium ion battery typically comprises a positive electrode, a negative electrode, an electrolyte, and a separator and generates electrical energy through oxidation-reduction reactions that occur when lithium ions are intercalated into and deintercalated from the positive electrode and the negative electrode.

In detail, based on the principle that lithium ions as charge carriers and electrons move between the positive electrode and the negative electrode, a series of processes, in which the lithium ions and electrons migrate to the positive electrode to be intercalated into a positive electrode active material during discharge and are deintercalated from the positive electrode active material to be intercalated into a negative electrode active material during charge, are repeated.

The negative and positive electrode active materials used in the lithium ion battery should have a crystal structure capable of reacting with the lithium ions and excellent electrical properties such that the lithium ion battery has high capacity and excellent cycle stability. Moreover, a side reaction between the active materials and electrolyte should not occur and a change in volume of an active material grid, which occurs during charge/discharge cycles, should be reduced.

Typical negative electrode active materials that satisfy the above characteristics are carbon materials, which are divided into crystalline carbon materials and non-crystalline carbon materials.

The crystalline carbon materials are mainly used in the secondary batteries and are divided into artificial graphite and natural graphite. The artificial graphite, such as mesocarbon fiber and mesocarbon microbeads, is expensive and has low capacity and thus is not widely used. While the natural graphite has high capacity, the irreversible capacity is large and thus is not efficient. Moreover, it has a laminar structure and thus cannot be formed with high density.

In connection with the above-described carbon materials, extensive research and development has continued to progress. However, the carbon materials have drawbacks such as a low theoretical capacity and a deterioration of cycle stability due to irreversible loss caused by a side reaction between the carbon and electrolyte.

Recently, extensive research on Group IV elements such as Si, Ge, Sn (e.g., Li—Si:4200 mAh/g, Li—Ge:1600 mAh/g, Li—Sn:990 mAh/g) having a theoretical capacity higher than that of graphite has been performed to substitute for the carbon materials. However, these materials have the disadvantage that a significant reduction in capacity due to charge/discharge cycles is caused by excessive volume expansion that occurs during alloying and dealloying reaction with lithium ions.

For this reason, metal oxides such as Fe₂O₃, CuO, MnO₂, CoO, etc., which can substitute for the carbon materials, have been suggested as negative electrode active materials. However, the capacity of these materials is achieved by an exchange reaction between a metal and a metal oxide, not by the intercalation/deintercalation reaction of lithium ions, and thus the reaction rate is low due to the nature of the reaction between the metal and metal oxide that occurs during charge/discharge cycles. Moreover, the cycle characteristics are significantly reduced by local non-uniformity due to agglomeration of particles.

Extensive research on TiO₂ negative electrode active materials, which exhibit the capacity through the intercalation/deintercalation reaction, has been conducted to overcome the above-described drawbacks. The TiO₂ negative electrode active materials have the advantages that the amount of by-products generated from the side reaction with the electrolyte is small, it is possible to achieve high power, and the change in capacity under repeated cycling is not very great.

However, the TiO₂ nanoparticles agglomerate together or electrons should be transferred to a current collector through the surface of a plurality of nanoparticles, and thus they have significant limitations in achieving high power characteristics. For these reasons, there is a need for the development of a new type of negative electrode active materials for lithium secondary batteries, which can easily transfer electrons and prevent agglomeration of nanoparticles.

Recently, in order to solve these problems, a method of preparing a nanostructured negative electrode active material comprising an iron oxide (Fe₃O₄) by growing Cu nanorods on a current collector has been reported [P. L. Taberna et al., Nature Mater. 3 (2006) 567]. According to the report, the high rate characteristics can be obtained by an increase in electron transfer efficiency due to an increase in the surface area of an electrode and a decrease in electron transfer distance.

The above information disclosed in this Background section is only for enhancement of understanding of the background of the invention and therefore it may contain information that does not form the prior art that is already known in this country to a person of ordinary skill in the art.

### SUMMARY OF THE DISCLOSURE

As mentioned above, the TiO₂ nanoparticles as an existing negative electrode active material agglomerate together during wet synthesis or during charge/discharge cycles, and thus the electrical contact with a current collector is cut off, which reduces the reaction rate. Moreover, the generated electrons should reach the current collector through the surface of a plurality of nanoparticles, and thus the electron transfer efficiency is not good.

Therefore, the present invention has been made in an effort to solve the above-described problems associated with prior art. Accordingly, the present invention provides a method of preparing a new negative electrode active material for a secondary battery with high rate characteristics by growing conductive ITO nanowires directly on a current collector and adsorbing TiO₂ nanoparticles having stable cycle characteristics on the surface of the current collector, and an improved lithium ion secondary battery including the same.

To achieve the above objects, the present invention provides an electrode comprising a substrate and an active material layer formed on the substrate, wherein the active material layer comprises a nanostructured conductor formed on the substrate and comprising a metal or metal oxide and an active material formed on the surface of the nanostructured conductor and comprising metal oxide nanoparticles.

Here, the nanostructured conductor may have a nanowire structure.

Moreover, the present invention provides a method of preparing an electrode including a nanocomposite active material, the method comprising the steps of: forming a nanostructured conductor comprising a metal or metal oxide on a substrate; and forming an active material comprising metal oxide nanoparticles on the surface of the nanostructured conductor.

Here, the step of forming the nanostructured conductor may comprise the steps of: placing a metal powder precursor for forming the nanostructured conductor in a tube of an electric furnace; placing a substrate with a catalyst layer in the tube of the electric furnace; and growing the nanostructured conductor on the substrate by creating a vacuum state in the tube of the electric furnace, increasing the temperature, and maintaining the temperature of the substrate in a predetermined range such that the metal powder precursor is evaporated.

The nanostructured conductor may have a nanowire structure.

The step of forming the active material comprising metal oxide nanoparticles may comprise the steps of: placing a substrate including the nanostructured conductor in a tube of an electric furnace; placing a metal oxide target for forming the metal oxide nanoparticles in the tube of the electric furnace; and allowing the nanoparticles produced from the metal oxide target to be adsorbed on the surface of the nanostructured conductor by supplying oxygen to the tube of the electric furnace and, at the same time, irradiating a pulsed laser beam on the metal oxide target.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a schematic diagram showing an example of a metal evaporation apparatus used to prepare ITO nanowires as a conductor in accordance with a preferred embodiment of the present invention.

FIG. 2 is a field emission scanning electron microscope (FESEM) image of ITO nanowires prepared on a SUS current collector substrate by metal evaporation in accordance with a preferred embodiment of the present invention.

FIG. 3 is an X-ray powder diffraction pattern of ITO nanowires prepared on a SUS current collector substrate by metal evaporation in accordance with a preferred embodiment of the present invention.

FIG. 4 is a graph showing electrical characteristics of ITO single nanowires prepared by metal evaporation in accordance with a preferred embodiment of the present invention.

FIG. 5 is a schematic diagram showing an example of a pulsed laser deposition apparatus used to adsorb TiO₂ nanoparticles as a negative electrode active material on the surface of ITO nanowires in accordance with a preferred embodiment of the present invention.

FIG. 6 is an FESEM image of TiO₂ nanoparticles adsorbed on the surface of ITO nanowires in accordance with a preferred embodiment of the present invention.

FIG. 7 is high-resolution transmission electron microscope (HRTEM) images of TiO₂ nanoparticles adsorbed on the surface of ITO nanowires in accordance with a preferred embodiment of the present invention.

FIG. 8 is a graph showing charging-discharging curves of the structure in which TiO₂ nanoparticles are adsorbed on the surface of ITO nanowires in accordance with a preferred embodiment of the present invention.

FIG. 9 is a graph showing variation of the discharge-charge specific capacity versus cycle number of the structure in which TiO₂ nanoparticles are adsorbed on the surface of ITO nanowires in accordance with a preferred embodiment of the present invention.

FIG. 10 is FESEM and HRTEM images of a structure, in which TiO₂ nanoparticles are adsorbed on the surface of ITO nanowires, in a discharge state after performing 400 charge/discharge cycles at a current corresponding to 60 C.

### DETAILED DESCRIPTION

Hereinafter, preferred embodiments of the present invention will be described in detail with reference to the accompanying drawings.

The present invention provides an electrode including a nanocomposite active material and a method of preparing the same. The electrode is prepared by forming a nanostructured conductor comprising nanowires on an electrode substrate and forming an active material comprising metal oxide nanoparticles on the surface of the nanowires.

The electrode of the present invention can be used in various electrochemical devices such as energy storage devices including secondary batteries, supercapacitors, etc., photocatalyst elements, thermoelectric elements, or composite elements thereof. The electrode of the present invention can be applied to a lithium secondary battery, in which intercalation/deintercalation of lithium ions is performed, and especially applied to a negative electrode of the lithium secondary battery. Here, the nanocomposite active material may be used as a negative electrode active material of the secondary battery such as the lithium secondary battery.

First, the electrode according to the present invention comprises a substrate and an active material layer formed on the substrate. The active material layer comprises a nanostructured conductor formed on the substrate and comprising a metal or metal oxide and an active material formed on the surface of the nanostructured conductor and comprising metal oxide nanoparticles.

Here, the nanostructured conductor formed on the substrate of the electrode and the active material comprising nanoparticles constitute the nanocomposite active material (i.e., the active material layer). The nanostructured conductor may comprise a metal selected from the group consisting of Cu, Co, Cr, Ti, Mo, Ni, W, Pt, Ag, Au, Al, Sn, In, and combinations thereof or a metal oxide selected from the group consisting of indium tin oxide (ITO), fluorine-doped tin oxide (FTO), and aluminum-doped zinc oxide (AZO).

The nanostructured conductor may be nanowires comprising a metal or metal oxide and having a diameter of 20 to 100 nm and a length of 10 to 100 μm.

The metal oxide nanoparticles of the active material may comprise a metal oxide comprising a metal selected from the group consisting of Ti, Ni, Fe, Co, Cu, Mn, Sn, V, In, Zn, and combinations thereof and having a diameter of 5 to 20 nm.

The electrode comprising the nanocomposite active material containing nanowires and nanoparticles according to the present invention can be used as various electrochemical devices such as secondary batteries, supercapacitors, thermoelectric elements, photocatalyst elements, or composite elements thereof. Especially, an ITO-TiO₂ negative electrode active material, which is prepared by adsorbing TiO₂ nanoparticles on the surface of ITO nanowires, may be used as the negative electrode active material for the lithium secondary battery.

When the ITO-TiO₂ negative electrode active material is used, the charge/discharge rate of the lithium secondary battery can be significantly improved, and the problems of the conventional negative electrode active materials, such as low power characteristics, deterioration of cycle characteristics, etc., can be improved. Especially, the ITO-TiO₂ negative electrode active material having a structure in which nanoparticles are adsorbed on nanowires having a high specific surface area exhibits excellent electrochemical properties in terms of charge/discharge rate and cycle characteristics due to effective electron transfer and prevention of agglomeration of particles.

Moreover, the present invention provides an electrochemical device comprising an electrode having a structure in which metal oxide nanoparticles are adsorbed on self-supported nanowires comprising a metal or metal oxide having a high specific surface area. Here, the electrochemical device may be a secondary battery such as a lithium secondary battery, a supercapacitor, etc., a thermoelectric element, a photocatalyst element, or a composite element thereof.

When the nanocomposite active material comprising nanowires and nanoparticles is used as the negative electrode active material (e.g., ITO-TiO₂ negative electrode active material) in the electrochemical device of the present invention, it is possible to provide a self-supported lithium secondary battery having a charge/discharge capacity of about 200 mAh/g or higher at 60 C.

Meanwhile, the structure of the nanocomposite active material comprising nanowires and nanoparticles (e.g., ITO nanowires and TiO₂ nanoparticles) according to the present invention can be implemented by a relatively simple synthesis method, and especially, can be formed directly on the electrode substrate (i.e., current collector substrate).

That is, the nanocomposite active material may be prepared by growing metal or metal oxide nanowires directly on the electrode substrate by vapor deposition (or metal evaporation) and adsorbing nanoparticles on the surface of the nanowires. For example, the negative electrode of the lithium secondary battery comprising a combination of ITO and TiO₂ is prepared by growing ITO nanowires as a negative electrode material directly on the electrode substrate, i.e., the current collector substrate, by vapor deposition and adsorbing TiO₂ nanoparticles as a substantial negative electrode active material on the surface of the ITO nanowires.

As such, in the present invention, the nanowires are grown by vapor deposition, and thus it is possible to obtain excellent crystallinity compared to synthesis methods such as electrochemical methods. Moreover, the TiO₂ nanoparticles are adsorbed on the self-supported ITO nanowires directly grown on the current collector substrate, and thus it is possible to improve the electrical contact between the current collector substrate and the negative electrode active material.

The method of preparing the electrode according to the present invention, which includes the steps of forming a nanostructured conductor comprising a metal or metal oxide on the substrate and forming an active material comprising metal oxide nanoparticles on the surface of the nanostructured conductor, will be described in more detail below.

Here, the step of forming the nanostructured conductor, in which metal evaporation is used, may include the steps of placing a metal powder precursor for forming the nanostructured conductor in a tube of an electric furnace, placing a substrate with a catalyst layer in the tube of the electric furnace, and forming the nanostructured conductor on the substrate by creating a vacuum state in the tube of the electric furnace, increasing the temperature, and maintaining the temperature of the substrate in a predetermined range such that the metal powder precursor is evaporated.

In the step of forming the nanostructured conductor on the substrate, the inside of the tube of the electric furnace is maintained in a vacuum state without injection of gas and, preferably, the temperature of the substrate in the vacuum state is maintained in the rage of 500 to 600° C.

The metal powder precursor may comprise at least one metal powder selected from the group consisting of Cu, Co, Cr, Ti, Mo, Ni, W, Pt, Ag, Au, Al, Sn, In, and combinations thereof.

Here, when at least two metal powders (e.g., indium powder and tin powder) are used together to form the ITO nanostructured conductor, the at least two different powders are not mixed together but are placed in the tube of the electric furnace separately.

Moreover, the substrate may be a metal substrate with a catalyst layer comprising an element selected from the group consisting of Au, Sn, In, Pt, and Bi. Preferably, a current collector substrate prepared by depositing gold (Au) with a predetermined thickness on a stainless steel (SUS) substrate may be used to prepare a secondary battery.

The step of forming the active material comprising metal oxide nanoparticles on the surface of the nanostructured conductor may include the steps of placing a substrate including the nanostructured conductor in a tube of an electric furnace, placing a metal oxide target for forming the metal oxide nanoparticles in the tube of the electric furnace, and allowing the nanoparticles produced from the metal oxide target to be adsorbed on the surface of the nanostructured conductor by supplying oxygen to the tube of the electric furnace and, at the same time, irradiating a pulsed laser beam on the metal oxide target.

Here, the metal oxide target may be a compound comprising a metal selected from the group consisting of Ti, Ni, Fe, Co, Cu, Mn, Sn, V, In, Zn, and combinations thereof. During pulsed laser deposition, a difference in height is provided between the metal oxide target and the substrate such that the metal oxide nanoparticles are uniformly adsorbed on the surface of the nanostructured conductor.

Next, the present invention will be described in more detail with reference to examples, but the present invention is not limited by the examples.

As an example of the present invention, a negative electrode including a nanocomposite active material of the present invention is prepared by forming three-dimensional ITO nanowires on an electrode substrate, i.e., a current collector substrate of stainless steel (SUS) with a catalyst layer, and adsorbing TiO₂ nanoparticles on the surface of the ITO nanowires.

The shape of the ITO-TiO₂ nanocomposite active material (i.e., ITO-TiO₂ hybrid nanostructure) comprising the ITO nanowires formed on the current collector substrate and the TiO₂ nanoparticles adsorbed on the surface of the ITO nanowires was observed using a field emission scanning electron microscope (FESEM) and a high-resolution transmission electron microscope (HRTEM), and the phase and crystal structure of the synthesized product were identified using an X-ray diffraction (XRD) pattern.

[Preparing Nanostructured Conductor on Current Collector Substrate with ITO Nanowires]

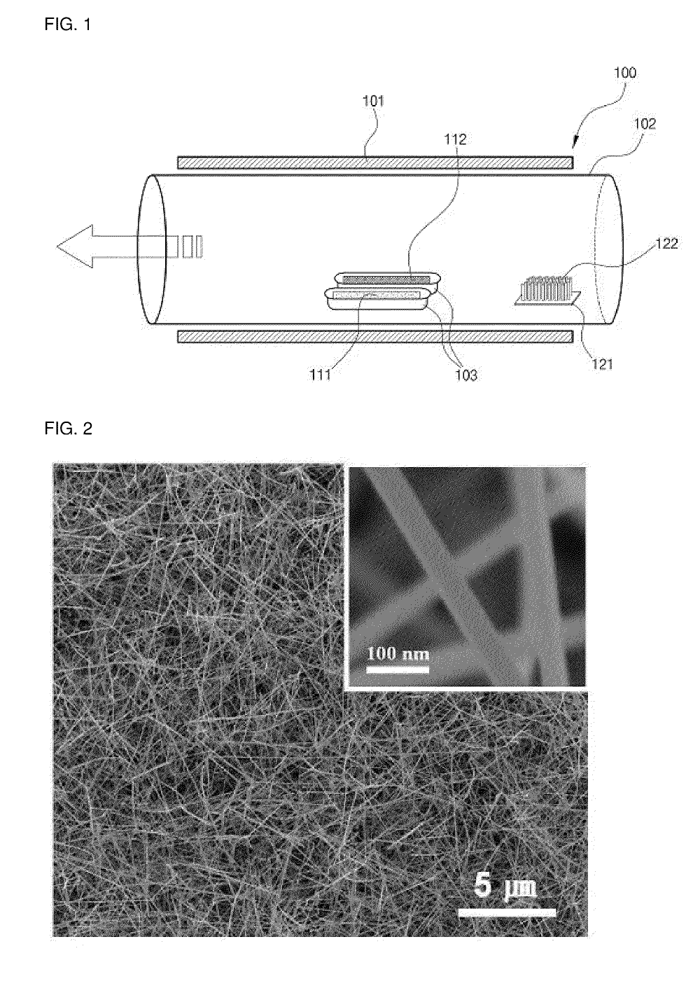

FIG. 1 is a schematic diagram showing an example of a metal evaporation apparatus used to prepare ITO nanowires as a conductor, in which the inside of a tube of an electric furnace of the metal evaporation apparatus is schematically shown. Reference numeral 121 denotes an electrode substrate used as a current collector substrate.

The synthesis method of ITO nanowires 122 provided by the present invention is metal evaporation using metal powder precursors, in which indium powder 111 and tin powder 112 are not mixed together but are placed in a tube 102 of an electric furnace 100 separately.

In the case where the precursors of the two metal powders 111 and 112 are mixed together and evaporated, the indium having a low melting point is first melted and evaporated or forms a mixed solid solution during temperature increase, and thus it is not easy to control the ratio of the precursors.

On the contrary, according to the method provided by the present invention, the two metal powders 111 and 112 are not mixed together but are placed in the tube 102, and thus the above-described problem does not occur. Moreover, it is possible to control the doping concentration of tin according to an appropriate ratio of the indium powder 111 and tin powder 112 in the ITO nanowires 122 grown under constant conditions.

In the synthesis method (i.e., metal evaporation) of ITO nanowires according to the present invention, the metal powders are used as the precursors, and thus there is an advantage that the growth temperature of nanowires is low. Typically, in the case where ITO nanowires are synthesized by pyrolysis of an oxide source, the nanowires are synthesized at a temperature of 900° C. or higher, and thus the conductive substrate such as stainless steel (SUS) cannot serve as a current collector due to oxidation.

Therefore, the present invention employs the metal evaporation to synthesize the ITO nanowires on the substrate at a temperature of 540° C. or less, and thus it is possible to prevent the oxidation of the conductive substrate such as stainless steel (SUS), i.e., current collector substrate 121. Moreover, in a typical synthesis of ITO nanowires, an oxide is formed by forcibly injecting oxygen gas. However, in the present invention, the ITO nanowires can be synthesized without injection of oxygen gas.

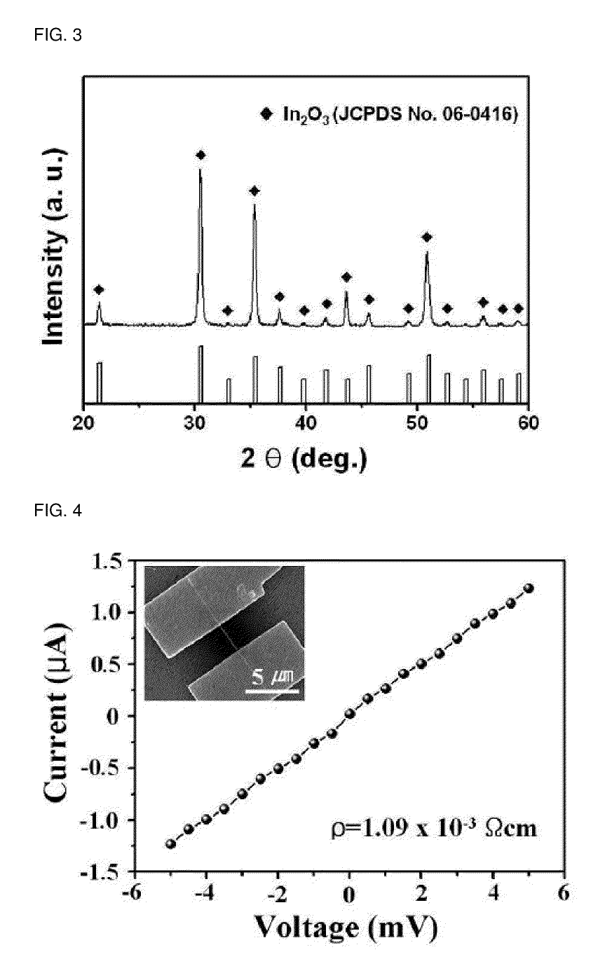

FIG. 2 is a field emission scanning electron microscope (FESEM) image of ITO nanowires prepared by the synthesis method of the present invention. The nanowires having a diameter of 100 nm or less and a length of several tens of μm and formed on the current collector substrate exhibit a high density. Moreover, it can be seen from FIG. 3 of the X-ray powder diffraction pattern that the ITO nanowires are grown without a second phase. Moreover, as shown in FIG. 4, it can be seen that the self-supported ITO nanowires prepared by the synthesis method of the present invention have electrical properties that can serve as a conductor of the electrode substrate (i.e., current collector substrate).

In detail, the indium powder 111 and the tin powder 112, which have a size of about 325 mesh, were used as the raw materials to prepare the ITO nanowires. As the electrode substrate (i.e., current collector substrate), a stainless steel substrate, in which gold (Au) serving as a catalyst is deposited in a thickness of about 5 nm, is used. An appropriate amount of each of the raw material powders 111 and 112 (e.g., a weight ratio of indium to tin of 9:1) was placed in an alumina boat 103 and located in the middle of a quartz tube 102 having an outer diameter of 24 mm and a length of 800 mm. The ITO nanowires 122 were grown at about 0.05 torr for 30 minutes at a temperature of 695° C. by increasing the temperature by 30° C. per minute without carrier and reactant gas. As a result, desired nanowires 122 could be obtained on the electrode substrate 121 located at the end of the upstream side of the quartz tube 102 and, at this time, the temperature of the substrate 121 was 540° C. or less.

[Preparing TiO₂ on the Surface of ITO Nanowires]

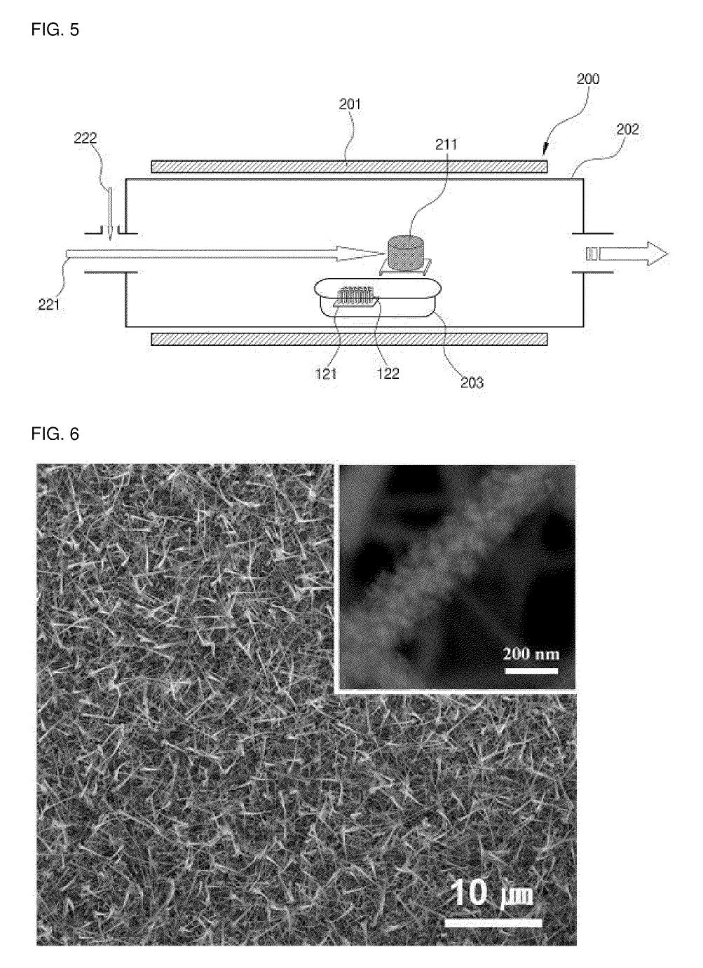

Pulsed laser deposition was used to form TiO₂ nanoparticles as a negative electrode active material on the surface of the synthesized ITO nanowires. FIG. 5 is a schematic diagram showing an example of the pulsed laser deposition apparatus. The structure provided by the present invention was prepared by allowing TiO₂ nanoparticles to grow by irradiating a pulsed laser beam 221 on a TiO₂ bulk target 211 on the surface of three-dimensional ITO nanowires 122 grown on a current collector substrate 121 in a tube 202 of an electric furnace 200.

As shown in FIG. 5, the substrate 121 was located at the bottom of an alumina boat 203 and the target 211 is located at the top of the alumina boat 203 at the downstream side from the substrate 121 such that a different in height is provided between them. If there was no difference in height between the substrate 121 and the target 211, the negative electrode active material nanoparticles would not be adsorbed or uniformly distributed, and thus it is preferable that the difference in height be provided between the substrate 121 and the target 211.

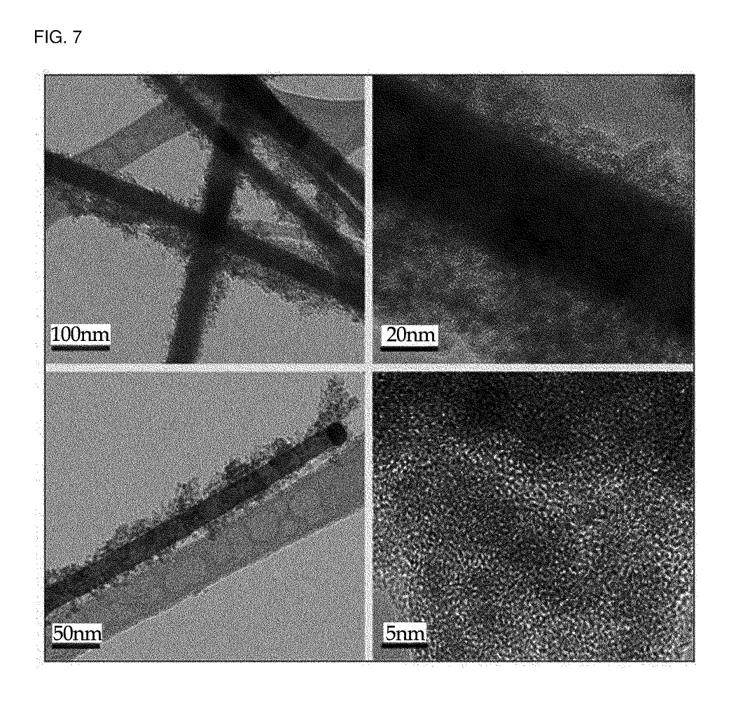

FIG. 6 is an FESEM image of the ITO-TiO₂ nanocomposite active material, from which it can be seen that the TiO₂ nanoparticles were uniformly grown on the surface of the ITO nanowires. FIG. 7 shows high-resolution transmission electron microscope (HRTEM) images of the ITO-TiO₂ nanocomposite active material, from which it can be seen that the TiO₂ nanoparticles having a size of about 10 nm or less were well distributed on the surface of the ITO nanowires having a diameter of about 40 nm.

The temperature during the synthesis of the negative electrode active material was 400° C., at which the current collector substrate 121 was not oxidized and, even when oxygen gas 222 was supplied at a flow rate of 10 sccm to the tube 202 of the electric furnace 200, no oxidation occurred. If the flow rate of oxygen gas 222 is increased, the possibility of oxidation of the current collector substrate 121 is increased and further it is difficult to obtain spherical TiO₂ nanoparticles having the same size. Moreover, even when the oxygen gas is supplied at a flow rate of 10 sccm or less, it is difficult to control the shape.

In detail, when the TiO₂ nanoparticles were formed on the surface of the ITO nanowires by the pulsed laser deposition, the target required to synthesize the TiO₂ nanoparticles was prepared by sintering anatase powder having a purity of 99% or more at 105° C. for 6 hours. A Lambda Physik Compex 205 excimer laser generating UV radiation at a wavelength of 248 nm using KrF gas was used as a laser source. Moreover, the TiO₂ nanoparticles were prepared under the conditions of a temperature of 400° C., a pulse repetition period of 5 Hz, an oxygen partial pressure of about 1 torr, a synthesis time of 40 minutes, and an energy density of 1.6 J/cm². The substrate 121 on which the ITO nanowires were grown was located below the upstream side of the target 211 located in the middle of the tube 202 of the electric furnace 200 with a difference in height, thereby obtaining TiO₂ nanoparticles adsorbed on the surface of the ITO nanowires.

[Preparation and Measurement of Half Cell for Evaluation of Electrochemical Properties]

The structure comprising the ITO nanowires (as a conductor) and the TiO₂ nanoparticles (as a negative electrode active material) prepared in the above-described manner can be used in an electrode of an electrochemical device such as a lithium secondary battery. Therefore, in the present invention, an electrode for the lithium secondary battery was prepared and a half cell was formed using the electrode to evaluate the electrochemical properties in order to determine whether the above structure could be used as the electrode of the lithium secondary battery. The lithium secondary battery shows excellent electrochemical performance when the amount of lithium ions capable of reacting with the negative electrode active material per unit molecular is higher and the particle agglomeration is more reduced during discharge.

The negative electrode structure prepared in the above-described manner, in which the ITO nanowires as the conductor were formed on the SUS current collector substrate and the TiO₂ nanoparticles as the negative electrode active material were adsorbed on the surface of the ITO nanowires, can be applied directly to a cell without pretreatment and additional process of thinly coating the negative electrode active material on the current collector.

The half cell was prepared by interposing an electrolyte and a separator between metal lithium as a negative electrode and the electrode prepared in the present invention as a positive electrode. As the electrolyte, a mixed solution in which LiPF₆ was dissolved in a mixture of ethylene carbonate (EC) and dimethyl carbonate (DMC) in a volume ratio of 1:1 was used. The preparation process was performed in a glove box in which an inert gas such as argon was filled.

The thus prepared Swagelok-type cell was operated in a Galvanostatic mode at a voltage of 1.0 to 2.2 V using a charge-discharge cycler (WBCS 3000, WonATech., Korea), and the electrochemical properties were evaluated by analyzing the change in voltage according to the time or capacity.

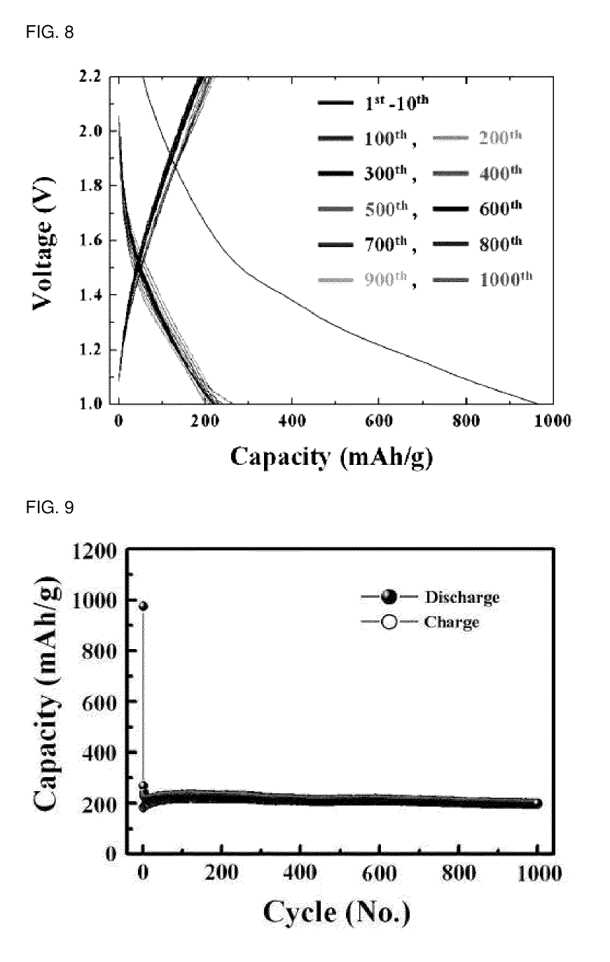

1,000 charge/discharge cycles were performed on the prepared cell at a voltage of 1.0 to 2.2 V and a constant current density corresponding to 60 C (refer to FIGS. 8 and 9). As a result of the evaluation of the properties of the prepared cell as the secondary battery, it can be seen that there was no significant change in capacity at about ˜200 mAh/g, which was higher than the theoretical capacity of TiO₂, 168 mAh/g, after 1,000 cycles. Moreover, the capacity of the prepared cell exceeded the theoretical capacity even at 60 C, and thus it was expected that the prepared cell can be charged within a short period of time when it is commercialized.

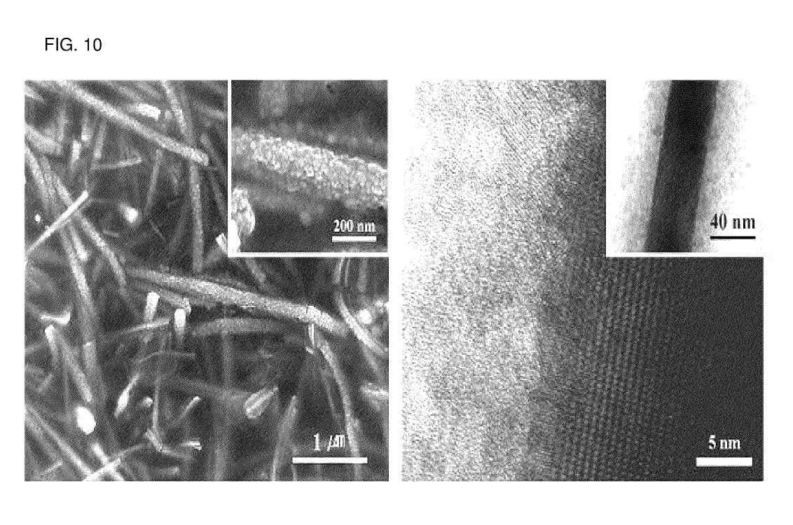

The reason that the prepared cell showed the excellent secondary battery characteristics was that the shape of the cell was maintained as the collapse of ITO nanowires or the agglomeration of TiO₂ nanoparticles did not occur such that the surface area of the negative electrode active material absorbing lithium ions and the electron transfer effect through the conductive nanowire electrode were not changed from the initial charge/discharge cycle (refer to FIG. 10).

As described above, according to the present invention, it is possible to solve the problems of the negative electrode active materials for the conventional lithium secondary batteries, such as low power, low charge/discharge rate, and deterioration of cycle characteristics.

For example, when the negative electrode comprising ITO nanowires as a conductor and TiO₂ nanoparticles as a negative electrode active material according to the present invention is used, it is possible to significantly improve the charge/discharge rate of the lithium secondary battery and solve the problems of the conventional negative electrode active materials, such as low power characteristics, deterioration of cycle characteristics, etc.

Especially, the structure in which nanoparticles are adsorbed and supported on nanowires having a high specific surface area exhibits excellent electrochemical properties in terms of charge/discharge rate and cycle characteristics due to effective electron transfer and prevention of agglomeration of particles. Moreover, the initial capacity of the secondary battery can be maintained for a long time.

The structure of the nanocomposite active material comprising nanowires and nanoparticles according to the present invention can be implemented by a relatively simple synthesis method, and especially, can be formed directly on the electrode substrate (i.e., current collector substrate).

That is, the nanocomposite active material is prepared by growing metal or metal oxide nanowires directly on the electrode substrate by vapor deposition (or metal evaporation) and adsorbing nanoparticles on the surface of the nanowires. For example, the negative electrode of the lithium secondary battery comprising a combination of ITO and TiO₂ is prepared by growing ITO nanowires as a negative electrode material directly on the electrode substrate, i.e., the current collector substrate, by vapor deposition and adsorbing TiO₂ nanoparticles as a substantial negative electrode active material on the surface of the ITO nanowires.

Moreover, in the present invention, the nanowires are grown by vapor deposition, and thus it is possible to obtain excellent crystallinity compared to synthesis methods such as electrochemical methods. Further, the TiO₂ nanoparticles are adsorbed on the self-supported ITO nanowires directly grown on the current collector substrate, and thus it is possible to improve the electrical contact between the current collector substrate and the negative electrode active material.

Furthermore, the ITO-TiO₂ nanocomposite active material, i.e., the ITO-TiO₂ hybrid nanostructure, can be effectively used in various electrochemical devices such as supercapacitors, etc., as well as (negative electrode) active materials for lithium (ion) secondary batteries.

The invention has been described in detail with reference to preferred embodiments thereof. However, it will be appreciated by those skilled in the art that changes may be made in these embodiments without departing from the principles and spirit of the invention, the scope of which is defined in the appended claims and their equivalents.

1. An electrode comprising a substrate and an active material layer formed on the substrate,
wherein the active material layer comprises a nanostructured conductor formed on the substrate and comprising a metal or metal oxide and an active material formed on the surface of the nanostructured conductor and comprising metal oxide nanoparticles.

2. The electrode of claim 1, wherein the nanostructured conductor comprises a metal selected from the group consisting of Cu, Co, Cr, Ti, Mo, Ni, W, Pt, Ag, Au, Al, Sn, In, and combinations thereof or a metal oxide selected from the group consisting of indium tin oxide (ITO), fluorine-doped tin oxide (FTO), and aluminum-doped zinc oxide (AZO).

3. The electrode of claim 1, wherein the nanostructured conductor has a nanowire structure.

4. The electrode of claim 3, wherein the nanostructured conductor has a diameter of 20 to 100 nm and a length of 10 to 100 μm.

5. The electrode of claim 1, wherein the metal oxide nanoparticles comprise a metal oxide comprising a metal selected from the group consisting of Ti, Ni, Fe, Co, Cu, Mn, Sn, V, In, Zn, and combinations thereof.

6. The electrode of claim 1, wherein the metal oxide nanoparticles have a diameter of 5 to 20 nm.

7. A method of preparing an electrode including a nanocomposite active material, the method comprising the steps of:
forming a nanostructured conductor comprising a metal or metal oxide on a substrate; and
forming an active material comprising metal oxide nanoparticles on the surface of the nanostructured conductor.

8. The method of claim 7, wherein the step of forming the nanostructured conductor comprises the steps of:
placing a metal powder precursor for forming the nanostructured conductor in a tube of an electric furnace;
placing a substrate with a catalyst layer in the tube of the electric furnace; and
growing the nanostructured conductor on the substrate by creating a vacuum state in the tube of the electric furnace, increasing the temperature, and maintaining the temperature of the substrate in a predetermined range such that the metal powder precursor is evaporated.

9. The method of claim 8, wherein in the step of forming the nanostructured conductor, the temperature of the substrate is maintained in the range of 500 to 600° C.

10. The method of claim 8, wherein in the step of forming the nanostructured conductor, the inside of the tube of the electric furnace is maintained in a vacuum state without injection of gas.

11. The method of claim 8, wherein the metal powder precursor comprises at least one metal powder selected from the group consisting of Cu, Co, Cr, Ti, Mo, Ni, W, Pt, Ag, Au, Al, Sn, In, and combinations thereof.

12. The method of claim 8, wherein when at least two metal powders are used together as the metal powder precursor, the at least two different powders are not mixed together but are placed in the tube of the electric furnace separately.

13. The method of claim 8, wherein the substrate is a metal substrate with a catalyst layer comprising an element selected from the group consisting of Au, Sn, In, Pt, and Bi.

14. The method of claim 13, wherein the substrate is a stainless steel (SUS) substrate with a catalyst layer prepared by depositing gold (Au) thereon.

15. The method of claim 7, wherein the nanostructured conductor has a nanowire structure.

16. The method of claim 7, wherein the step of forming the active material comprising metal oxide nanoparticles comprises the steps of:
placing a substrate including the nanostructured conductor in a tube of an electric furnace;
placing a metal oxide target for forming the metal oxide nanoparticles in the tube of the electric furnace; and
allowing the nanoparticles produced from the metal oxide target to be adsorbed on the surface of the nanostructured conductor by supplying oxygen to the tube of the electric furnace and, at the same time, irradiating a pulsed laser beam on the metal oxide target.

17. The method of claim 16, wherein the metal oxide target comprises a compound comprising a metal selected from the group consisting of Ti, Ni, Fe, Co, Cu, Mn, Sn, V, In, Zn, and combinations thereof.

18. The method of claim 16, wherein the pulsed laser beam is irradiated on the metal oxide target having a difference in height from the surface of the substrate.

19. An electrochemical device comprising the electrode of claim 1.

20. The electrochemical device of claim 19, wherein the electrochemical device is an energy storage device, a photocatalyst element, a thermoelectric element, or a composite element thereof, which comprises the electrode.

21. The electrochemical device of claim 20, wherein the energy storage device is a lithium secondary battery comprising the electrode as a negative electrode.

22. The electrochemical device of claim 21, wherein the lithium secondary battery has a charge/discharge capacitor of 200 mAh/g or higher at 60 C.

23. The electrochemical device of claim 20, wherein the energy storage device is a supercapacitor.

24. An electrochemical device comprising the electrode of claim 7.
